(19) United States
(12) Patent Application Publication
(10) Pub. No.: US 2026/0130037 A1
(43) Pub. Date: May 7, 2026

(54) SEMICONDUCTOR PACKAGE AND PHYSICAL-QUANTITY MEASUREMENT APPARATUS

(71) Applicant: Asahi Kasei Microdevices Corporation, Tokyo (JP)

(72) Inventor: Yuji GODA, Tokyo (JP)

(21) Appl. No.: 19/373,653

(22) Filed: Oct. 29, 2025

(30) Foreign Application Priority Data
Nov. 1, 2024 (JP) 2024-192643
Oct. 2, 2025 (JP) 2025-166214

(51) Int. Cl. H10H 29/85; G01N 21/25; G01N 21/3504; H10F 55/255; H10H 29/10

(52) U.S. Cl. CPC H10H 29/857; G01N 21/255; G01N 21/3504; H10F 55/255; H10H 29/10; G01N 2201/1211

(57) ABSTRACT

A semiconductor package may include: a pair of first input terminals arranged adjacent to each other, which is connected to a terminal pair of a first light-receiving element which outputs a first current signal as a function of a light reception amount of light emitted from a light source; a pair of second input terminals arranged adjacent to each other, which is connected to a terminal pair of a second light-receiving element which outputs a second current signal as a function of the light reception amount of light emitted from the light source; a third terminal arranged adjacent to one in the pair of first input terminals and to one in the pair of second input terminals; and a generation unit which generates a digital signal based on the first current signal and the second current signal.

The contents of the following patent application(s) are incorporated herein by reference:

NO. 2024-192643 filed in JP on Nov. 1, 2024

NO. 2025-166214 filed in JP on Oct. 2, 2025.

### BACKGROUND

### 1. TECHNICAL FIELD

The present invention relates to a semiconductor package and a physical-quantity measurement apparatus.

### 2. RELATED ART

Patent document 1 describes a gas sensor which performs A/D conversion on a measurement target gas signal which depends on a measurement target gas concentration and a reference signal which does not depend on the measurement target gas concentration, to estimate the measurement target gas concentration based on a ratio of these signals.

### RELATED ART DOCUMENT

### Patent Document

Patent Document 1: Japanese Patent Application Publication No. 2014-173896

### BRIEF DESCRIPTION OF THE DRAWINGS

FIG. 1 is a functional block diagram illustrating an example of a configuration of a gas sensor according to the present embodiment.

FIG. 2 illustrates an example of a pin arrangement of a circuit which constitutes the gas sensor according to the present embodiment.

FIG. 3 illustrates an example of a circuit configuration of a first light-receiving element and a signal processing IC.

### DESCRIPTION OF EXEMPLARY EMBODIMENTS

Hereinafter, the present invention will be described through embodiments of the invention, but the following embodiments do not limit the invention according to the claims. Further, not all of combinations of features described in the embodiments are essential to the solving means of the invention.

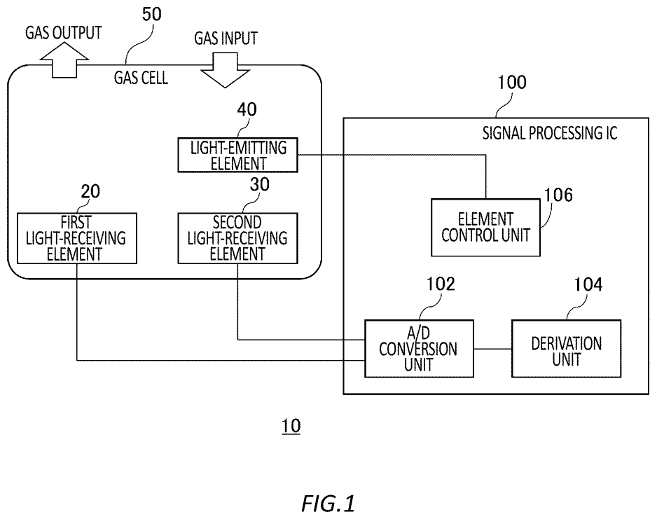

FIG. 1 is a functional block diagram illustrating an example of a configuration of a gas sensor 10. The gas sensor 10 includes a first light-receiving element 20, a second light-receiving element 30, a light-emitting element 40, a gas cell 50, and a signal processing IC 100. The gas sensor 10 is an example of a physical-quantity measurement apparatus which measures a particular physical quantity. The gas sensor 10 may be, for example, a breath sensor and may be an NDIR (Non-Dispersive Infrared) sensor utilizing an absorption wavelength specific to carbon dioxide contained in breath or in the atmosphere. Further, the gas sensor 10 may be, for example, an NDIR (Non-Dispersive Infrared) sensor utilizing an absorption wavelength specific to an alcohol component contained in breath. Furthermore, the gas sensor 10 may be, for example, an NDIR (Non-Dispersive Infrared) sensor utilizing an absorption wavelength specific to methane gas contained in the atmosphere. The gas sensor in the present embodiment can be applied to various kinds of equipment. The gas sensor can be used, for example: for environmental measurement in a building; for being mounted as small portable measurement equipment on mobile communication equipment such as a smartphone; for gas detection within a compartment in a means of transportation such as a car, a train or an aircraft; or the like.

According to the configuration of the gas sensor in the present embodiment, the gas sensor can be applied as a light-receiving/emitting apparatus for an application other than gas detection. That is, the contents of the disclosure derived by substituting the terms “optical concentration measurement apparatus”, “optical physical quantity measurement apparatus”, “light-receiving/emitting apparatus”, “optical apparatus”, and the like for the term “gas sensor” described above fall within the scope of the present disclosure. For example, these apparatuses make it possible to sense a state of an optical path space such as, as an example other than gas, presence/absence or a concentration of a certain component in a fluid. For example, these apparatuses can be used as, for example, a component sensing apparatus or a component concentration measurement apparatus for a substance, e.g., water or body fluid, that exists in an optical path space between a light-emitting element and a light-receiving unit. For example, when the substance that exists in the optical path space is blood, the component sensing apparatus or the component concentration measurement apparatus can be used for glucose concentration measurement in the blood or the like.

The component sensing apparatus or the component concentration measurement apparatus can measure a glucose concentration in blood by measuring absorption of light having a wavelength of 1 to 10 μm. For the glucose concentration measurement in the blood, it is preferable to measure absorption of light having a wavelength of 1.6 μm, 2.0 to 2.3 μm, and 9.6 μm. It is possible to construct a small, precise, and reliable non-invasive glucose concentration meter. For example, the glucose concentration meter thus described enables self-checking of a blood sugar level by a patient without causing any damage to the patient's skin, as would be caused in an invasive method. Further, based on the blood sugar level thus checked, it is possible to achieve management of more accurate administration (e.g., of insulin).

The gas cell 50 is configured such that target gas can enter and exit an interior of the gas cell 50. The first light-receiving element 20 for measurement, the second light-receiving element 30 for reference, and the light-emitting element 40 are arranged in the interior of the gas cell 50. The second light-receiving element 30 may be arranged adjacent to the light-emitting element 40. The second light-receiving element 30 and the light-emitting element 40 may also be configured as one semiconductor chip.

The interior of the gas cell 50 is desirably at least in part composed of a material that reflects light such that light emitted by the light-emitting element 40 is guided to the first light-receiving element 20 and/or the second light-receiving element 30. For example, the gas cell 50 is composed of a metal material such as aluminum, copper, and the like. Further, for example, the gas cell 50 may also be of resin, and at least a part of an inner surface thereof may have metal thin film of aluminum, copper, and the like. Further, the measurement target gas may be carbon dioxide, breath, alcohol (such as ethanol), methane, propane, hydrogen, ethylene, and MCH (methylcyclohexane). Further, the measurement target gas may be a toxic gas such as carbon monoxide, hydrogen sulfide, formaldehyde, and ammonia. Moreover, the measurement target gas may be a greenhouse gas such as dinitrogen monoxide and a refrigerant gas used for air conditioners, refrigerators, or the like.

The first light-receiving element 20 outputs a first current signal as a function of a light reception amount of light emitted from the light-emitting element 40. The second light-receiving element 30 outputs a second current signal as a function of a light reception amount of light emitted from the light-emitting element 40. The first current signal is a gas sensing signal, which depends on a measurement target gas concentration within the gas cell 50, and the second current signal is a reference signal, which does not depend on the measurement target gas concentration within the gas cell 50 or which has a certain degree of dependency different from that of the first current signal. The second light-receiving element 30 may be used for compensating for temperature change or temporal change in the first light-receiving element 20. That is, the reference signal may be used for compensating for temperature change or temporal change in the gas sensing signal.

The signal processing IC 100 includes an A/D conversion unit 102, a derivation unit 104, and an element control unit 106. The signal processing IC 100 is an example of a semiconductor package. The signal processing IC 100 calculates the measurement target gas concentration based on the first current signal and the second current signal. The measurement target gas concentration is an example of a particular physical quantity.

The A/D conversion unit 102 converts each of the first current signal and the second current signal, which are analog signals, into digital signals, and outputs a first digital signal and a second digital signal. The A/D conversion unit 102 is an example of a generation unit which generates a digital signal based on the first current signal and the second current signal. The derivation unit 104 calculates the measurement target gas concentration based on the first digital signal and the second digital signal. The second light-receiving element 30 is arranged adjacent to the light-emitting element 40 and may directly receive light emitted from the light-emitting element 40. That is, light emitted from the light-emitting element 40 may be received by the second light-receiving element 30 without passing any space in which the measurement target gas exists. Meanwhile, the first light-receiving element 20 may receive light of a wavelength range that remains without being absorbed by the gas in the gas cell 50, out of light emitted from the light-emitting element 40. The derivation unit 104 may calculate the measurement target gas concentration based on a ratio of a value indicated in the first digital signal to a value indicated in the second digital signal. When the second light-receiving element 30 is arranged spaced apart from the light-emitting element 40, light emitted from the light-emitting element 40 may be caused to pass through an optical filter which restricts a wavelength band of light to a wavelength band less affected by the measurement target gas, and light that has been transmitted through the optical filter may be received at the second light-receiving element 30.

The element control unit 106 controls light intensity of the light-emitting element 40. The light-emitting element 40 emits light having intensity as a function of a drive signal input from the element control unit 106. Emission light, which is light emitted by the light-emitting element 40, is incident on the first light-receiving element 20 and the second light-receiving element 30. The light-emitting element 40 outputs emission light having a wavelength including a part of an absorption wavelength band of the measurement target gas or the like. Further, the light-emitting element 40 outputs emission light having a wavelength band to which the first light-receiving element 20 and the second light-receiving element 30 are sensitive. For example, emission light of the light-emitting element 40 is light of an infrared region, light of an ultraviolet region, or light of another wavelength band. The light-emitting element 40 may be an LED, an incandescent bulb, a ceramic heater, a MEMS (Micro Electro Mechanical Systems) heater, or the like. The light-emitting element 40 in the present embodiment is a mid-infrared LED which emits infrared light.

The first light-receiving element 20 is sensitive to infrared light emitted by the light-emitting element 40. The first light-receiving element 20 outputs the first current signal as a function of light reception intensity of infrared light incident thereon. The second light-receiving element 30 is sensitive to infrared light emitted by the light-emitting element 40. The first light-receiving element 20 outputs the second current signal as a function of light reception intensity of infrared light incident thereon. The first current signal and the second current signal are input into the A/D conversion unit 102. The first light-receiving element 20 and the second light-receiving element 30 may be a quantum infrared sensor such as a photodiode; a thermal infrared sensor such as a pyroelectric sensor, a thermopile, or a bolometer; or the like. In the present embodiment, the first light-receiving element 20 and the second light-receiving element 30 are each a mid-infrared photodiode.

As described above, besides the first light-receiving element 20 for measurement of a gas concentration, the gas sensor 10 includes the second light-receiving element 30 for reference. The gas sensor 10 can suppress impact of noise such as variations of the light intensity emitted by the light-emitting element 40 and measure gas concentration stably and precisely.

It is effective to configure the signal processing IC 100 in an ASIC in order to achieve miniaturization of the gas sensor 10. However, change in the output of the first light-receiving element 20 for measurement of the gas concentration, i.e., the first current signal, as a function of the gas concentration is small. Therefore, when leakage current flows into wiring for connecting the first light-receiving element 20 and the signal processing IC 100 from other wiring of the gas sensor 10, or when leakage current outflows into the other wiring, then a large error can occur in the gas concentration measurement based on the first current signal. Miniaturization of the gas sensor 10 may cause a higher density of wiring, resulting in more frequent occurrence of leakage current.

The ASIC performs, for example, current-to-voltage conversion on the first current signal output by the first light-receiving element 20 and the second current signal output by the second light-receiving element 30, and inputs voltage obtained by the conversion into the A/D conversion unit. This current-to-voltage conversion circuit or the A/D conversion unit can be shared to use for both of the first current signal and the second current signal via a switch circuit, but at this time, in order to shorten wiring within the semiconductor package of the ASIC, it is preferable to arrange connection terminals of the ASIC for individually connecting to the first light-receiving element 20 and the second light-receiving element 30 to be close to each other. However, if the individual connection terminals of the first light-receiving element 20 and the second light-receiving element 30 are adjacent to each other, wiring of the first light-receiving element 20 for measurement and wiring of the second light-receiving element 30 for reference would be forced to be adjacent to each other, resulting in leakage current between these parts of wiring or making it difficult to take an additional anti-leakage measure such as shielded wiring.

Consequently, in the present embodiment, between one terminal in a pair of first input terminals which are two terminals arranged adjacent to each other, which is connected to a terminal pair of the first light-receiving element 20 for measurement, and one terminal in a pair of second input terminals which are other two terminals arranged adjacent to each other, which is connected to a terminal pair of the second light-receiving element 30 for reference, one pin of another terminal is arranged. The another terminal of the one pin is arranged adjacent to the one in the pair of first input terminals connected to the terminal pair of the first light-receiving element 20 for measurement and to the one in the pair of second input terminals connected to the terminal pair of the second light-receiving element 30 for reference. This reduces leakage current between the wiring of the first light-receiving element 20 for measurement and the wiring of the second light-receiving element 30 for reference. Further, it is made easier to take an additional measure such as shielded wiring or a guard ring for further reducing the leakage current. Here, the phrase “two terminals are arranged adjacent to each other” means that there is no other terminal arranged between the two terminals, regardless of a distance between the two terminals.

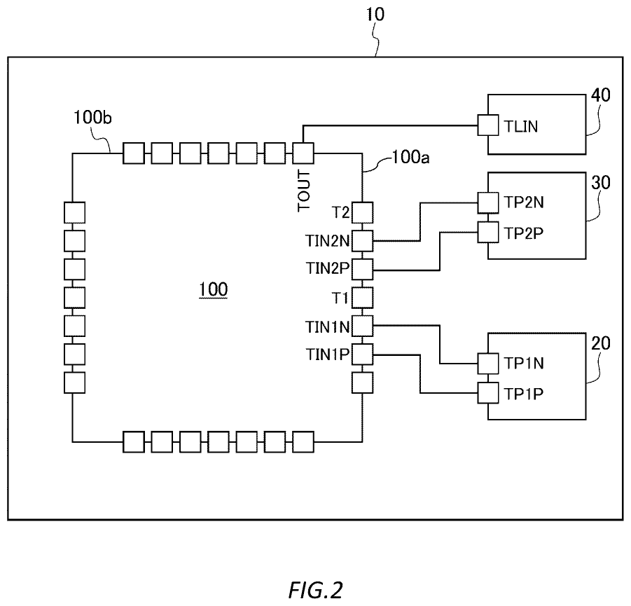

FIG. 2 illustrates an example of a pin arrangement of a circuit which constitutes the gas sensor 10 according to the present embodiment. As illustrated in FIG. 2, the signal processing IC 100, which is an ASIC, includes a plurality of terminals. The package of the signal processing IC 100 may be a QFN. The package may also be an LGA or a QFP.

The signal processing IC 100 may be rectangular in a plan view. The signal processing IC 100 includes a plurality of terminals arranged along an outer periphery thereof in the plan view when viewed from a mounting surface on a printed circuit board. The signal processing IC 100 includes at least, as the plurality of terminals, a pair of first input terminals TIN1N and TIN1P connected to a terminal pair of TP1N and TP1P of the first light-receiving element 20, and a pair of second input terminals TIN2N and TIN2P connected to a terminal pair of TP2N and TP2P of the second light-receiving element 30.

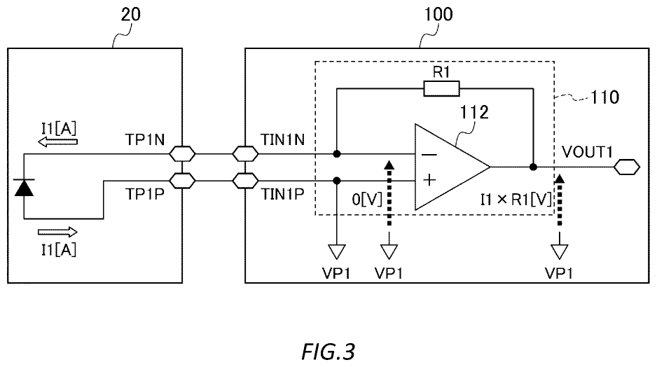

FIG. 3 illustrates an example of a circuit configuration of the first light-receiving element 20 and the signal processing IC 100. The signal processing IC 100 includes a current-to-voltage conversion circuit 110 which converts the first current signal output from the first light-receiving element 20 into a voltage signal. The current-to-voltage conversion circuit 110 includes an operational amplifier 112 and a feedback resistor R1. The current-to-voltage conversion circuit 110 converts a first current signal I1 input into the pair of first input terminals TIN1N and TIN1P via the terminal pair of TP1N and TP1P of the first light-receiving element 20 into a voltage signal I1×R1 to output it as VOUT1. The signal processing IC 100 may control such that potentials of the pair of first input terminals TIN1N and TIN1P are both a first internal potential VP1, which is a predetermined potential, in order to take the first current signal in the signal processing IC 100, and may control such that potentials of the pair of second input terminals TIN2N and TIN2P are both a second internal potential VP2, which is a predetermined potential, in order to take the second current signal in the signal processing IC 100. The first internal potential VP1 and the second internal potential VP2 may be equal potentials.

The signal processing IC 100 may further include a third terminal T1 arranged between the pair of first input terminals TIN1N and TIN1P and the pair of second input terminals TIN2N and TIN2P. The third terminal T1 is arranged adjacent to the first input terminal TIN1N, which is one in the pair of first input terminals, and to the second input terminal TIN2P, which is one in the pair of second input terminals. The third terminal T1 may output a constant potential. The third terminal T1 may be a voltage output terminal electrically connected to a guard ring surrounding at least one of the first light-receiving element 20 or the second light-receiving element 30 in the plan view, which applies a potential to the guard ring, wherein the potential applied to the guard ring by the third terminal T1 may be the first internal potential VP1 or the second internal potential VP2.

The pair of first input terminals TIN1N and TIN1P, the pair of second input terminals TIN2N and TIN2P, and the third terminal T1 may be arranged along the outer periphery of the signal processing IC 100 when viewed from the mounting surface of the signal processing IC 100. The pair of first input terminals TIN1N and TIN1P, the pair of second input terminals TIN2N and TIN2P, and the third terminal T1 may be arranged along a first edge 100a of the outer periphery of the signal processing IC 100 when viewed from the mounting surface of the signal processing IC 100.

If the package of the signal processing IC 100 is a QFN, then pair of first input terminals TIN1N and TIN1P, the pair of second input terminals TIN2N and TIN2P, and the third terminal T1 may be arranged to be spaced away from each other on the first edge 100a of the outer periphery of the signal processing IC 100 when viewed from the mounting surface of the signal processing IC 100. If the package of the signal processing IC 100 is an LGA, then the pair of first input terminals TIN1N and TIN1P, the pair of second input terminals TIN2N and TIN2P, and the third terminal T1 may be arranged to be spaced away from each other along the first edge 100a of the outer periphery of the signal processing IC 100 when viewed from the mounting surface of the signal processing IC 100. If the package of the signal processing IC 100 is a QFP, then the pair of first input terminals TIN1N and TIN1P, the pair of second input terminals TIN2N and TIN2P, and the third terminal T1 may be arranged to be protruding from a first side surface which appears as the first edge 100a of the outer periphery of the signal processing IC 100 and to be spaced away from each other when viewed from the mounting surface of the signal processing IC 100.

The signal processing IC 100 may further include a first output terminal TOUT. The signal processing IC 100 may have a functionality for driving a light-emitting element by voltage or current output from the first output terminal TOUT. At this time, the light-emitting element may be driven intermittently in a constant-voltage mode or a constant-current mode by voltage or current output from the first output terminal TOUT. Here, the term “intermittently” describes, for example, an operation, such as an operation of driving at a constant current of 100 mA for a certain part of a period, and ceasing to drive or driving at a sufficiently smaller current than 100 mA mentioned right before for the rest of the period. The signal processing IC 100 may further include a fourth terminal T2 that is provided between the first output terminal TOUT and the second input terminal TIN2N, which is another one in the pair of second input terminals TIN2N and TIN2P, and that is arranged adjacent to the second input terminal TIN2N. The first output terminal TOUT may be connected to a terminal TLIN of the light-emitting element 40. The fourth terminal T2 may be a voltage output terminal electrically connected to the guard ring surrounding the at least one of the first light-receiving element 20 or the second light-receiving element 30, which applies a potential to the guard ring, wherein the potential at the guard ring may be constant. Here, the phrase “the potential is constant” may encompass a deviation of approximately 20% from an average of potentials at the driving guard ring for any 80% range in a time period during which the gas sensor is driving. The phrase “the potential is constant” encompasses a case where the potential can be deemed as substantially constant when errors, such as potential fluctuations caused due to operations of peripheral circuits, potential fluctuations caused due to variations in device characteristics, and potential fluctuations caused due to temperature characteristics, are considered. Further, the potentials applied by the third terminal T1 and by the fourth terminal T2 may be equal potentials.

The pair of first input terminals TIN1N and TIN1P, the pair of second input terminals TIN2N and TIN2P, the third terminal T1, the fourth terminal T2, and the first output terminal TOUT may be arranged along the outer periphery of the signal processing IC 100 when viewed from the mounting surface of the signal processing IC 100. The pair of first input terminals TIN1N and TIN1P, the pair of second input terminals TIN2N and TIN2P, the third terminal T1, and the fourth terminal T2 may be arranged along the first edge 100a of the outer periphery of the signal processing IC 100 when viewed from the mounting surface of the signal processing IC 100, and the first output terminal TOUT may be arranged along a second edge 100b, which is different from the first edge 100a, of the outer periphery of the signal processing IC 100 when viewed from the mounting surface of the signal processing IC 100. The second edge 100b forms an angle with the first edge 100a.

If the package of the signal processing IC 100 is a QFN, then the pair of first input terminals TIN1N and TIN1P, the pair of second input terminals TIN2N and TIN2P, the third terminal T1, and the fourth terminal T2 may be arranged to be spaced away from each other on the first edge 100a of the outer periphery of the signal processing IC 100 when viewed from the mounting surface of the signal processing IC 100, and the first output terminal TOUT may be arranged on the second edge 100b, which is different from the first edge 100a, of the outer periphery of the signal processing IC 100 when viewed from the mounting surface of the signal processing IC 100.

If the package of the signal processing IC 100 is an LGA, then the pair of first input terminals TIN1N and TIN1P, the pair of second input terminals TIN2N and TIN2P, the third terminal T1, and the fourth terminal T2 may be arranged to be spaced away from each other along the first edge 100a of the outer periphery of the signal processing IC 100 when viewed from the mounting surface of the signal processing IC 100, and the first output terminal TOUT may be arranged along the second edge 100b, which is different from the first edge 100a, of the outer periphery of the signal processing IC 100 when viewed from the mounting surface of the signal processing IC 100.

If the package of the signal processing IC 100 is a QFP, then the pair of first input terminals TIN1N and TIN1P, the pair of second input terminals TIN2N and TIN2P, the third terminal T1, and the fourth terminal T2 may be arranged to be spaced away from each other and to be protruding from the first side surface which appears as the first edge 100a of the outer periphery of the signal processing IC 100 when viewed from the mounting surface of the signal processing IC 100, and the first output terminal TOUT may be arranged to be protruding from a second side surface which appears as the second edge 100b, which is different from the first edge 100a, of the outer periphery of the signal processing IC 100 when viewed from the mounting surface of the signal processing IC 100.

According to the signal processing IC 100 configured as described above, leakage current is reduced between the wiring of the first light-receiving element 20 for measurement and the wiring of the second light-receiving element 30 for reference by providing the third terminal T1 between the pair of first input terminals TIN1N and TIN1P and the pair of second input terminals TIN2N and TIN2P. Further, it is made easier to take an additional measure such as shielded wiring or a guard ring for further reducing the leakage current.

More specifically, the first output terminal TOUT outputs current or voltage to drive the light-emitting element 40. Since driving electrical power of the light-emitting element 40 is typically greater than a signal source, which is the second light-receiving element 30 in the present example, of second current signal input into the pair of second input terminals TIN2N and TIN2P, voltage or current handled by the first output terminal TOUT is greater than voltage or current handled by each of TIN2N and TIN2P in the pair of second input terminals. That is, potentially, leakage current is likely to flow into wiring connected to the pair of second input terminals TIN2N and TIN2P in response to the first output terminal TOUT driving the light-emitting element 40. Accordingly, leakage current caused in response to the first output terminal TOUT driving the light-emitting element 40 is reduced by having the fourth terminal T2 that is provided between the first output terminal TOUT and the second input terminal TIN2N, which is one in the pair of second input terminals, and that is arranged adjacent to the second input terminal TIN2N. Further, it is made easier to take an additional measure such as shielded wiring or a guard ring for further reducing the leakage current.

Further, since the first output terminal TOUT outputs current or voltage to drive the light-emitting element 40, it is desirable to make a width of wiring connected to the first output terminal TOUT wider to reduce wiring resistance. By arranging the first output terminal TOUT along the second edge 100b, which is different from the first edge 100a, of the outer periphery of the signal processing IC 100 when viewed from the mounting surface of the signal processing IC 100, an impact can be suppressed on wiring connected to the pair of first input terminals TIN1N and TIN1P, the pair of second input terminals TIN2N and TIN2P, the third terminal T1, and the fourth terminal T2, while making the width of the wiring connected to the first output terminal TOUT wider. Further, in comparison with when the first output terminal TOUT is on the first edge 100a, that is, when the second input terminal TIN2N, which is one in the pair of second input terminals, the fourth terminal T2, and the first output terminal TOUT are arranged adjacent to each other, the wiring connected to the first output terminal TOUT and the wiring connected to the second input terminal TIN2N can be spaced further apart, reducing leakage current. Further, it is made easier to take an additional measure such as shielded wiring or a guard ring for further reducing the leakage current.

Note that, in the present embodiment, the ASIC which is an IC performing signal processing in the gas sensor 10 and which calculates a measurement target gas concentration has been exemplarily described as the signal processing IC 100. However, as long as the semiconductor package includes two pairs of input terminals connected to individual terminal pairs of two elements which output a current signal, the semiconductor package can be applied to an ASIC other than the ASIC which calculates the measurement target gas concentration.

While the embodiments of the present invention have been described, the technical scope of the present invention is not limited to the above-described embodiments. It is apparent to persons skilled in the art that various alterations or improvements can be added to the above-described embodiments. It is also apparent from the claims that the embodiments added with such alterations or improvements can be included in the technical scope of the present invention.

Each process of the operations, procedures, steps, stages, and the like performed by an apparatus, a system, a program, and a method shown in the claims, the description, and the drawings can be performed in any order as long as the order is not indicated by “prior to,” “before,” or the like and as long as the output from a previous process is not used in a later process. Even if the operation flow is described using phrases such as “first” or “next” in the claims, the description, and the drawings, it does not necessarily mean that it must be performed in this order.

### Item 1

A semiconductor package comprising:
a pair of first input terminals arranged adjacent to each other, which is connected to a terminal pair of a first light-receiving element which outputs a first current signal as a function of a light reception amount of light emitted from a light source;
a pair of second input terminals arranged adjacent to each other, which is connected to a terminal pair of a second light-receiving element which outputs a second current signal as a function of the light reception amount of light emitted from the light source;
a third terminal arranged adjacent to one in the pair of first input terminals and to one in the pair of second input terminals; and a generation unit which generates a digital signal based on the first current signal and the second current signal.

### Item 2

The semiconductor package according to item 1, wherein the pair of first input terminals, the pair of second input terminals, and the third terminal are arranged along an outer periphery of the semiconductor package when viewed from a mounting surface of the semiconductor package.

### Item 3

The semiconductor package according to item 1, wherein the pair of first input terminals, the pair of second input terminals, and the third terminal are arranged along a first edge of an outer periphery of the semiconductor package when viewed from a mounting surface of the semiconductor package.

### Item 4

The semiconductor package according to item 1, wherein the pair of first input terminals, the pair of second input terminals, and the third terminal are arranged on a first edge of an outer periphery of the semiconductor package when viewed from a mounting surface of the semiconductor package.

### Item 5

The semiconductor package according to item 1, further comprising: a first output terminal which outputs current to a third element; and a fourth terminal which is provided between the first output terminal and another one in the pair of second input terminals, and which is arranged adjacent to the another one in the pair of second input terminals.

### Item 6

The semiconductor package according to item 5, wherein the pair of first input terminals, the pair of second input terminals, the third terminal, the first output terminal, and the fourth terminal are arranged along an outer periphery of the semiconductor package when viewed from a mounting surface of the semiconductor package.

### Item 7

The semiconductor package according to item 5, wherein the pair of first input terminals, the pair of second input terminals, and the third terminal are arranged along a first edge of an outer periphery of the semiconductor package when viewed from a mounting surface of the semiconductor package, and the first output terminal is arranged along a second edge, which is different from the first edge, of the outer periphery of the semiconductor package when viewed from the mounting surface of the semiconductor package.

### Item 8

The semiconductor package according to item 5, wherein the pair of first input terminals, the pair of second input terminals, and the third terminal are arranged on a first edge of an outer periphery of the semiconductor package when viewed from a mounting surface of the semiconductor package, and the first output terminal is arranged on a second edge, which is different from the first edge, of the outer periphery of the semiconductor package when viewed from the mounting surface of the semiconductor package.

### Item 9

The semiconductor package according to item 5, wherein the third element is the light source.

### Item 10

The semiconductor package according to item 1, wherein the third terminal is a voltage output terminal which outputs a constant potential.

### Item 11

The semiconductor package according to item 1, wherein the second light-receiving element is used for compensating for temperature change or temporal change in the first light-receiving element.

### Item 12

A physical-quantity measurement apparatus comprising:
the semiconductor package according to any one of items 1 to 11,wherein
the physical-quantity measurement apparatus measures a physical quantity based on the digital signal.

### Item 13

The physical-quantity measurement apparatus according to item 12,further comprising the first light-receiving element and the second light-receiving element.

### Item 14

A physical-quantity measurement apparatus comprising:
the semiconductor package according to item 5; and
the first light-receiving element, the second light-receiving element, and the light source, which is the third element, wherein
the physical-quantity measurement apparatus measures a physical quantity based on the digital signal.

### Item 15

A semiconductor package comprising:
a pair of first input terminals connected to a terminal pair of a first element which outputs a first current signal;
a pair of second input terminals connected to a terminal pair of a second element which outputs a second current signal; and
a third terminal arranged between the pair of first input terminals and the pair of second input terminals.

### EXPLANATION OF REFERENCES

10: gas sensor;
20: first light-receiving element;
30: second light-receiving element;
40: light-emitting element;
50: gas cell;
100: signal processing IC;
102: A/D conversion unit;
104: derivation unit;
106: element control unit;
TIN1P and TIN1N: pair of first current input terminals;
TIN2P and TIN2N: pair of second current input terminals;
T1: third terminal;
T1: fourth terminal;
Tout: First Output Terminal;
TP1N and TP1P: terminal pair of first light-receiving element 20;
TP2N and TP2P: terminal pair of second light-receiving element 30; and
TLIN: terminal of light-emitting element 40.

What is claimed is:

1. A semiconductor package comprising:
a pair of first input terminals arranged adjacent to each other, which is connected to a terminal pair of a first light-receiving element which outputs a first current signal as a function of a light reception amount of light emitted from a light source;
a pair of second input terminals arranged adjacent to each other, which is connected to a terminal pair of a second light-receiving element which outputs a second current signal as a function of the light reception amount of light emitted from the light source;
a third terminal arranged adjacent to one in the pair of first input terminals and to one in the pair of second input terminals; and
a generation unit which generates a digital signal based on the first current signal and the second current signal.

2. The semiconductor package according to claim 1, wherein the pair of first input terminals, the pair of second input terminals, and the third terminal are arranged along an outer periphery of the semiconductor package when viewed from a mounting surface of the semiconductor package.

3. The semiconductor package according to claim 1, wherein the pair of first input terminals, the pair of second input terminals, and the third terminal are arranged along a first edge of an outer periphery of the semiconductor package when viewed from a mounting surface of the semiconductor package.

4. The semiconductor package according to claim 1, wherein the pair of first input terminals, the pair of second input terminals, and the third terminal are arranged on a first edge of an outer periphery of the semiconductor package when viewed from a mounting surface of the semiconductor package.

5. The semiconductor package according to claim 1, further comprising:
a first output terminal which outputs current to a third element; and
a fourth terminal which is provided between the first output terminal and another one in the pair of second input terminals, and which is arranged adjacent to the another one in the pair of second input terminals.

6. The semiconductor package according to claim 5, wherein the pair of first input terminals, the pair of second input terminals, the third terminal, the first output terminal, and the fourth terminal are arranged along an outer periphery of the semiconductor package when viewed from a mounting surface of the semiconductor package.

7. The semiconductor package according to claim 5, wherein the pair of first input terminals, the pair of second input terminals, and the third terminal are arranged along a first edge of an outer periphery of the semiconductor package when viewed from a mounting surface of the semiconductor package, and the first output terminal is arranged along a second edge, which is different from the first edge, of the outer periphery of the semiconductor package when viewed from the mounting surface of the semiconductor package.

8. The semiconductor package according to claim 5, wherein the pair of first input terminals, the pair of second input terminals, and the third terminal are arranged on a first edge of an outer periphery of the semiconductor package when viewed from a mounting surface of the semiconductor package, and the first output terminal is arranged on a second edge, which is different from the first edge, of the outer periphery of the semiconductor package when viewed from the mounting surface of the semiconductor package.

9. The semiconductor package according to claim 5, wherein the third element is the light source.

10. The semiconductor package according to claim 1, wherein the third terminal is a voltage output terminal which outputs a constant potential.

11. The semiconductor package according to claim 5, wherein the third terminal is a voltage output terminal which outputs a constant potential.

12. The semiconductor package according to claim 1, wherein the second light-receiving element is used for compensating for temperature change or temporal change in the first light-receiving element.

13. The semiconductor package according to claim 5, wherein the second light-receiving element is used for compensating for temperature change or temporal change in the first light-receiving element.

14. A physical-quantity measurement apparatus comprising:
the semiconductor package according to claim 1, wherein
the physical-quantity measurement apparatus measures a physical quantity based on the digital signal.

15. The physical-quantity measurement apparatus according to claim 14, further comprising the first light-receiving element and the second light-receiving element.

16. A physical-quantity measurement apparatus comprising:
the semiconductor package according to claim 5; and
the first light-receiving element, the second light-receiving element, and the light source, which is the third element, wherein
the physical-quantity measurement apparatus measures a physical quantity based on the digital signal.

17. The physical-quantity measurement apparatus according to claim 16, wherein the third terminal is a voltage output terminal which outputs a constant potential.

18. The physical-quantity measurement apparatus according to claim 16, wherein the second light-receiving element is used for compensating for temperature change or temporal change in the first light-receiving element.

19. A semiconductor package comprising:
a pair of first input terminals connected to a terminal pair of a first element which outputs a first current signal;
a pair of second input terminals connected to a terminal pair of a second element which outputs a second current signal; and
a third terminal arranged between the pair of first input terminals and
the pair of second input terminals.
